(19) United States
(12) Patent Application Publication
(10) Pub. No.: US 2026/0341806 A1
(43) Pub. Date: Oct. 29, 2026

(54) ELECTRONIC ASSEMBLY FOR A HIGH-VOLTAGE BATTERY OF A MOTOR VEHICLE AND METHOD FOR POPULATING A HOUSING OF A HIGH-VOLTAGE BATTERY FOR A MOTOR VEHICLE

(71) Applicant: Lisa Dräxlmaier GmbH, Vilsbiburg (DE)

(72) Inventor: Andreas BRINKMANN, Dachau (DE)

(73) Assignee: Lisa Dräxlmaier GmbH, Vilsbiburg (DE)

(21) Appl. No.: 19/102,382

(22) PCT Filed: Jul. 21, 2023
(86) PCT No.: PCT/EP2023/070252

§ 371 Date: Feb. 8, 2025

(30) Foreign Application Priority Data
Aug. 12, 2022 (DE) 10 2022 120 485.5

(51) Int. Cl. H01M 10/42; B60R 16/033; H01M 10/625; H01M 10/658; H01M 50/204; H01M 50/24; H01M 50/249; H01M 50/284; H01M 50/293; H05K 1/02

(52) U.S. Cl. CPC H01M 10/425; H01M 10/625; H01M 10/658; H01M 50/204; H01M 50/24; H01M 50/249; H01M 50/284; H01M 50/293; B60R 16/033; H01M 2220/20; H05K 1/0256; H05K 2201/10037

(57) ABSTRACT

An electronic assembly for a high-voltage battery of a motor vehicle is disclosed. The assembly includes a printed circuit board equipped with electronic components, on the underside of which is arranged an insulation layer designed as high-voltage insulation, which covers at least most of the underside of the printed circuit board and is designed as a contact surface for mounting the electronic assembly on a housing of the high-voltage battery. The invention also relates to a method for equipping a housing of a high-voltage battery for a motor vehicle with at least one such electronic module.

### CROSS REFERENCE TO RELATED APPLICATIONS

This application is a US National Stage Application of International Application PCT/EP2023/070252, filed Jul. 21, 2023, which claims priority to German Patent Application DE102022120485.5, filed Aug. 12, 2022, the content of the both of which is incorporated herein by reference.

### BACKGROUND OF THE INVENTION

### Field of the Invention

The present invention relates to an electronic assembly for a high-voltage battery of a motor vehicle and to a method for equipping a housing of a high-voltage battery for a motor vehicle with at least one such electronic assembly.

### Description of Related Art

In electrically powered vehicles, the battery cells of a high-voltage battery usually have to be adjusted in terms of their electrical charge distribution, which is also referred to as balancing. So-called balancers are used for this purpose, which can, for example, be electronic assemblies that may have special integrated circuits. Such assemblies and their circuits usually have to be thermally insulated on the one hand and electrically insulated on the other, as high-voltage batteries usually have very high voltages.

In addition, the assembly of such electronic assemblies, which are intended to function as balancers, for example, can be quite difficult, as such electronic assemblies should be subjected to as little mechanical stress as possible, for example through twisting or warping. In addition, challenges can arise with regard to the thermal dissipation of such electronic assemblies and with regard to electrical insulation. Both can make it difficult to mount such electronic assemblies on a high-voltage battery housing.

### BRIEF SUMMARY OF THE INVENTION

A purpose and task of the invention disclosed herein is to provide particularly simple and effective electrical insulation of an electronic assembly for a high-voltage battery in a motor vehicle.

This task is solved by the objects of the presently disclosed invention. Features, advantages and possible embodiments which are set out in the description for one of the objects are to be regarded at least analogously as features, advantages and possible embodiments of other objects and of any possible combination of objects of the presently disclosed invention.

An electronic assembly according to the invention for a high-voltage battery of a motor vehicle comprises a printed circuit board equipped with electronic components, on the underside of which an insulation layer designed as high-voltage insulation is arranged, which covers at least most of the underside of the printed circuit board and is designed as a contact surface for mounting the electronic assembly on a battery housing of the high-voltage battery. By at least for the most part, it is to be understood that the insulation layer designed as high-voltage insulation covers more than half of the underside of the printed circuit board. This can also be understood to mean that the insulation layer designed as high-voltage insulation completely covers the underside of the circuit board. Values in between, i.e. from a coverage of more than 50% to 100%, are possible. In particular, all electrically conductive parts of the underside of the printed circuit board can be covered by the insulation layer. The insulation layer designed as high-voltage insulation can in particular be flat or even, especially on its outer side, which is used to arrange the electronic assembly on the outside of the battery housing of the relevant high-voltage battery.

The underside of the printed circuit board can be the side facing away from the electronic components. The outside of the insulation layer can be the side of the insulation layer facing away from the underside of the printed circuit board. The electronic components can be mounted on an upper side of the printed circuit board. In addition, the electronic assembly can also have electrical components. The printed circuit board may be a so-called PCB. In other words, the instant printed circuit board may be a well-known printed circuit board. The printed circuit board can be a single-layer PCB or a multi-layer PCB. The electronic components on the top side can be connected to the corresponding circuits of the individual layers, for example by drilling plated holes in the desired layer.

In other words, the electronic assembly is an assembled circuit board that also has an insulation layer designed as high-voltage insulation on the underside of the circuit board. Since the electronic assembly is designed for use in or on a high-voltage battery, the high-voltage insulation plays a particularly important role. In the invention, it is intended to locate the electrical insulation in or on the printed circuit board, namely in the form of the insulation layer designed as high-voltage insulation, which is provided on the underside of the printed circuit board. This insulation layer may in particular not be part of the printed circuit board, but a separate layer. In contrast to the invention, a relatively large amount of gap filler and often several insulating films are traditionally used, which are arranged between such electronic assemblies and a battery housing of a high-voltage battery in order to electrically insulate the electronic assembly from the housing of the high-voltage battery, which is usually made of metal. This makes attaching or mounting such electronic assemblies to the housing of a high-voltage battery very complex.

In the electronic assembly according to the invention, however, the insulation layer designed as high-voltage insulation is already part of the electronic assembly. In other words, high-voltage insulation is therefore provided directly on the printed circuit board of the electronic assembly. The electronic assembly can therefore be easily attached to the relevant housing of the high-voltage battery by directly or indirectly attaching the electronic assembly with its insulation layer designed as high-voltage insulation to the outside of the housing. It is no longer necessary to provide further measures for electrically insulating the electronic assembly from the housing of the high-voltage battery, since the high-voltage insulation in the form of said insulation layer is already an integral part of the electronic assembly according to the invention.

In contrast to conventional methods, it is therefore no longer necessary, for example, to provide protective films, insulating varnishes or the like before or during assembly of the electronic assembly on the housing of the high-voltage battery. By means of the electronic assembly according to the invention, a particularly simple and effective electrical insulation of the electronic assembly with respect to a housing of a high-voltage battery is thus made possible.

One possible embodiment of the electronic assembly is that the electronic assembly is designed to ensure a uniform electrical charge distribution in at least some battery cells of the high-voltage battery when the electronic assembly is electrically conductively connected to the high-voltage battery. In other words, the electronic assembly can therefore be a so-called balancer or the electronic assembly can be designed to act as a balancer. The said electronic components with which the printed circuit board of the electronic assembly is equipped can, for example, have correspondingly suitable circuits and also other electrical and/or electronic components. Especially when the electronic assembly acts as a balancer, both the high-voltage insulation and the thermal dissipation of the electronic assembly play a particularly important role. The fact that the underside of the circuit board is at least largely covered by the insulation layer designed as high-voltage insulation means that particularly reliable electrical insulation of the electronic assembly from the housing and from the rest of the high-voltage battery can be ensured. The insulation layer designed as high-voltage insulation also serves as a contact surface for mounting the electronic assembly to the battery housing of the high-voltage battery and can be designed or formed in such a way that particularly good, reliable thermal dissipation, especially of the electronic components of the electronic assembly, can be enabled during operation. This can ensure that the electronic assembly does not overheat, especially if it acts as a balancer in said high-voltage battery.

A further possible embodiment of the invention provides that the insulation layer designed as high-voltage insulation can ensure insulation of up to 3.5 kV. As a result, particularly reliable high-voltage insulation can be ensured by the insulation layer during operation of the electronic assembly, i.e. when it is mounted on said high-voltage battery.

According to a further possible embodiment of the invention, it is provided that the insulating layer comprises polyimide. Polyimides have particularly good properties with regard to electrical insulation. It may also be provided that the insulating layer is made of polyimide.

In a further possible embodiment of the invention, it is provided that the insulation layer is between 25 and 50 μm thick. This can be provided in particular in connection with the insulation layer comprising polyimide. The heat transfer from the electronic assembly, in particular from its electronic components, to the relevant housing of the high-voltage battery can be ensured due to the very thin insulation layer, which is only between 25 and 50 μm thick. At the same time, this thickness ensures reliable high-voltage insulation.

According to a further possible embodiment of the invention, it is provided that the insulation layer is laminated onto the underside of the printed circuit board. The printed circuit board of the electronic assembly can be manufactured and assembled in a completely conventional manner, after which the polyimide material is then laminated onto the underside of the printed circuit board. This can take place both at the PCB manufacturer and in a downstream process step, for example at an automotive supplier. Lamination allows the insulation layer to be applied to the underside of the PCB in a particularly simple and reliable manner. A large part of the underside of the PCB can be provided with the insulation layer.

An alternative possible embodiment of the invention provides that the insulation layer comprises FR4 or is made of FR. FR4 refers to a class of flame-retardant and flame-retardant composite materials consisting of epoxy resin and glass fiber fabric. The abbreviation FR stands for Flame Retardant. FR4 usually has a fairly high dielectric strength, for example in the range of 20 to 60 kV/mm. The fact that the insulation layer contains or is made of FR4 means that it can provide particularly reliable high-voltage insulation.

In a further possible embodiment of the invention, it is provided that the FR4 comprises or is a no-flow prepreg. In this context, it may be provided that the insulation layer of FR4 is laminated to the underside of the printed circuit board. The fact that the insulation layer comprising FR4 has or consists of a no-flow prepreg makes it possible to ensure that the insulation layer retains its shape during the lamination process. Among other things, this can ensure that the insulation layer retains the desired layer thickness or also has the desired layer thickness after the lamination process. The insulation layer comprising FR4 can be 50 μm to 150 μm thick, for example. This ensures particularly good high-voltage insulation on the one hand and good heat dissipation from the electronic assembly, in particular its electronic components, to the housing of the high-voltage battery on the other.

An alternative possible embodiment of the invention provides for the insulation layer to be pressed onto the underside of the printed circuit board. If the printed circuit board is a multilayer printed circuit board, its layers can be produced first, after which the insulation layer comprising FR4, for example, can be pressed, drilled and plated through with the remaining layers. By pressing the insulation layer onto the underside of the PCB, a particularly simple and reliable connection between the insulation layer and the PCB can be ensured.

In the method, according to the invention, for fitting a housing of a high-voltage battery for a motor vehicle, at least the electronic assembly according to the invention or a possible embodiment of the electronic assembly is attached to the battery housing of the high-voltage battery, with the insulation layer designed as high-voltage insulation being arranged directly on the battery housing or by means of a gap filler. The insulation layer designed as high-voltage insulation can be arranged directly on the battery housing, i.e. without any additional material in between. Alternatively, it is possible to provide a gap filler between the insulation layer designed as high-voltage insulation and the battery housing, in particular without any other material, i.e. only the gap filler. In addition to compensating for unevenness, the gap filler can be used to connect the insulation layer designed as high-voltage insulation to the battery housing, in particular to bond it, so that the insulation layer is connected to the battery housing via the gap filler. The electronic module can be arranged on the outside or inside of the high-voltage battery housing. It is also possible to arrange several of the electronic assemblies on the battery housing with their respective insulation layers designed as high-voltage insulation during the process or during the assembly of the high-voltage battery housing. Equipping the housing of the high-voltage battery with the electronic assembly is particularly simple, as the electrical insulation is completely shifted into the electronic assembly, namely because the insulation layer designed as high-voltage insulation is part of the electronic assembly. This means that no further precautions need to be taken when fitting the housing in order to electrically shield or insulate the electronic assembly from the battery housing. Otherwise costly measures for electrical insulation can thus be omitted, for example it is not necessary to apply a protective film to the electronic assembly, to provide the battery housing with an insulating varnish or a film and the like. Overall, the method according to the invention thus results in a particularly simple and reliable electrical insulation of the electronic assembly with respect to the housing of the high-voltage battery.

Further advantages, features and details of the invention can be seen from the following description of possible embodiments and from the drawing. The features and combinations of features mentioned above in the description as well as the features and combinations of features shown below in the figure description and/or in the figures alone can be used not only in the combination indicated in each case, but also in other combinations or on their own, without departing from the scope of the invention.

### BRIEF DESCRIPTION OF THE SEVERAL VIEWS OF THE DRAWINGS

Further advantages, features, and details of the various embodiments of this disclosure will become apparent from the ensuing description of a preferred exemplary embodiment and with the aid of the drawings. The features and combinations of features recited below in the description, as well as the features and feature combination shown after that in the drawing description or in the drawings alone, may be used not only in the particular combination recited, but also in other combinations on their own, without departing from the scope of the disclosure.

In the following, an advantageous embodiment of the invention is explained with reference to the accompanying figures.

FIG. 1 depicts a schematic top view of an electronic assembly for a high-voltage battery of a motor vehicle, which has a printed circuit board fitted with electronic components;

FIG. 2 depicts a schematic side view of the electronic assembly, showing an insulation layer designed as high-voltage insulation, which is arranged on the underside of the printed circuit board;

FIG. 3 depicts a schematic top view of the electronic assembly from below, so that the insulation layer designed as high-voltage insulation can be seen; and

FIG. 4 depicts a schematic representation of a housing of a high-voltage battery, with several of the electronic assemblies on the outside of the housing of the high-voltage battery.

In the figures, identical or functionally identical elements are marked with the same reference symbols.

### DETAILED DESCRIPTION OF THE INVENTION

As used throughout the present disclosure, unless specifically stated otherwise, the term “or” encompasses all possible combinations, except where infeasible. For example, the expression “A or B” shall mean A alone, B alone, or A and B together. If it is stated that a component includes “A, B, or C”, then, unless specifically stated otherwise or infeasible, the component may include A, or B, or C, or A and B, or A and C, or B and C, or A and B and C. Expressions such as “at least one of” do not necessarily modify an entirety of the following list and do not necessarily modify each member of the list, such that “at least one of “A, B, and C” should be understood as including only one of A, only one of B, only one of C, or any combination of A, B, and C.

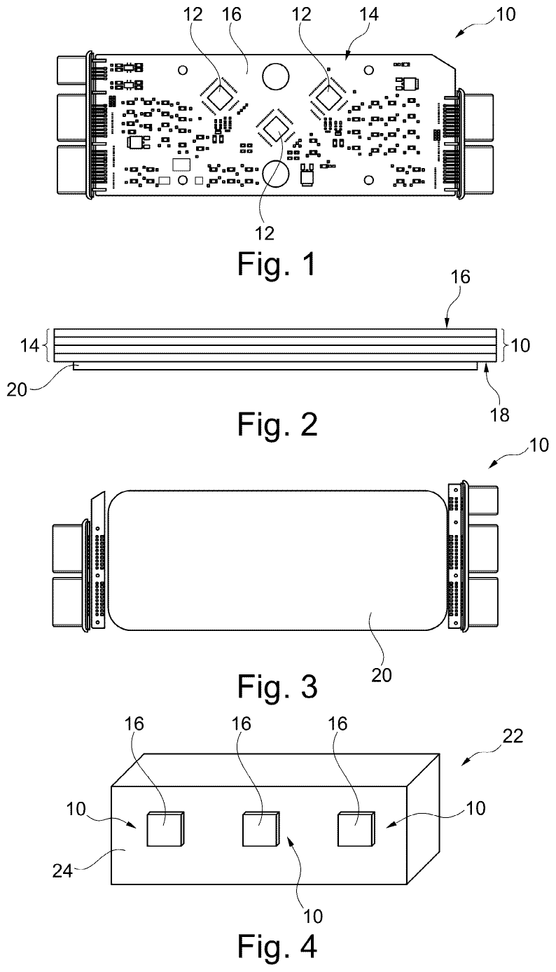

An electronic assembly 10 for a high-voltage battery of a motor vehicle, not shown here, is shown in a top view in FIG. 1. The electronic assembly 10 comprises a printed circuit board 14 fitted with electronic components 12. For the sake of clarity, not all electronic components have been provided with reference symbols. Some of the electronic components may be integrated circuits, for example. The electronic assembly 10 is designed to ensure a uniform electrical charge distribution in at least some of the battery cells of the relevant high-voltage battery on which it can be mounted. In other words, the electronic assembly 10 can act as a balancer.

FIG. 2 shows a schematic side view of the electronic assembly 10. As indicated here, the printed circuit board 14 can consist of several layers. The electronic components 12 are not shown here. While-as can be seen in FIG. 1—the electronic components 12 are arranged on a top side 16 of the printed circuit board 14, an insulation layer 20 designed as high-voltage insulation is arranged on a bottom side 18 of the printed circuit board 14. This insulation layer 20 covers the underside 18 of the printed circuit board 14 at least for the most part and serves as a contact surface for mounting the electronic assembly 10 on a battery housing of the relevant high-voltage battery. Contrary to the present embodiment, the insulating layer 20 can also be bordered on the side by one or more layers of the printed circuit board 14, for example. The insulation layer 20 can, for example, end at the same height as the rest of the printed circuit board 14. In other words, the insulation layer 20 and the bottom layer of the printed circuit board 14 could form an at least substantially flat underside of the electronic assembly 10. Depending on the requirements for the high-voltage insulation and the material composition of the insulation layer 20, it can also be so thick that it protrudes above the printed circuit board 14, e.g. by one third to one half of its own thickness.

In FIG. 3, the electronic assembly 10 is shown in a top view from below, so that the large-area and flat insulation layer 20 designed as high-voltage insulation can be seen. The insulation layer 20 designed as high-voltage insulation can provide insulation up to 2.5 kV. The insulation layer can be made of polyimide, for example. The insulation layer can be between 25 and 50 μm thick. The insulation layer 20 can, for example, be laminated to the underside 18 during the manufacture of the electronic assembly 10.

Alternatively, the insulation layer 20 can also be made of FR4. In particular, it may be provided that the insulation layer 20 made of FR4 is a no-flow prepreg. Prepreg is short for pre-impregnated fibers. Prepregs are usually textile fiber matrix semi-finished products pre-impregnated with reaction resins, which are cured under temperature and pressure to produce components. The insulation layer 20 made from FR4 can, for example, be 80 μm thick. The insulation layer 20 can, for example, be laminated onto the underside 18 of the printed circuit board 14. Alternatively, it is also possible to press the insulation layer 20 onto the underside 18 of the printed circuit board 14. In terms of production technology, it is possible, for example, that only the layers of the printed circuit board 14 are produced first, after which the insulation layer 20 is pressed, drilled and plated through as the fifth layer.

FIG. 4 shows a housing 22 of an unspecified high-voltage battery of a motor vehicle in a schematic perspective view. Three of the electronic assemblies 10 have been attached to an outer side 24 of the housing 22. In order to equip the housing 22 of the high-voltage battery, which is not specified, the electronic assemblies 10 are therefore attached to the housing 22 of the high-voltage battery, with the insulation layers 20 designed as high-voltage insulation being arranged on the outside of the housing 22 either directly or merely by means of a gap filler. The function of the electrical insulation is therefore integrated into the respective electronic assemblies 10, namely in the form of said insulation layer 20 on the underside 18 of the respective printed circuit boards 14. When attaching the electronic assemblies 10 to the housing 22, it is therefore not necessary to provide additional measures for electrical insulation between the electronic assembly 10 and the housing 22. If necessary, a gap filler is provided between the insulation layer 20 and the outside 24 of the housing 22. This can help to enable particularly good heat transfer from the electronic assemblies 10 to the housing 22. The housing 22 is particularly easy to assemble thanks to the integrated additional insulation layer 20 designed as high-voltage insulation. By selecting the appropriate material and dimensioning the thickness of the insulation layer 20, both good electrical insulation from the housing 22 and a good thermal connection to the housing 22 can be ensured.

It should also be noted that “comprehensive” does not include any other elements or steps and “one” or “a” does not exclude a plurality. Furthermore, it should be noted that features or steps described with reference to one of the above embodiments may also be used in combination with other features or steps of other embodiments described above. Reference signs in the claims are not to be regarded as a limitation.

What is claimed is:

1. An electronic assembly for a high-voltage battery of a motor vehicle having a housing, the electronic assembly comprising:
a printed circuit board comprising electronic components and an insulating laver arranged on an underside of the printed circuit board,
wherein the insulating at least largely covers the underside of the printed circuit board; and
wherein the insulating layer is configured and arranged to be a contact surface configured to enable a mounting of the electronic assembly on the housing of the high-voltage battery.

2. The electronic assembly according to claim 1, wherein
the high-voltage battery comprises one or more battery cells, and
the electronic assembly is configured to ensure a uniform electrical charge distribution across the one or more battery cells of the high-voltage battery when the electronic assembly is electrically and conductively connected to the high-voltage battery.

3. The electronic assembly according to claim 1, wherein the insulation layer is configured as high-voltage insulation configured to provide insulation up to 3.5 kV.

4. The electronic module according to claim 1, wherein
the insulating layer comprises polyimide.

5. The electronic assembly according to claim 4, wherein
the insulation layer is between 25 and 50 μm thick.

6. The electronic assembly according to claim 1, wherein the insulation layer comprises a class of flame-retardant and flame-retardant composite materials consisting of epoxy resin and glass fiber fabric.

7. The electronic assembly according to claim 6, wherein the a class of flame-retardant and flame-retardant composite materials consisting of epoxy resin and fiber fabric comprises a No Flow Prepreg.

8. The electronic assembly according to claim 6, wherein the insulation layer is 50 μm to 150 μm thick.

9. The electronic module according to claim 1, wherein the insulation layer is arranged laminated to the underside of the printed circuit board.

10. The electronic assembly according to claim 1, wherein the insulation layer is arranged pressed onto the underside of the printed circuit board.

11. A method for fitting a housing of a high-voltage battery configured to operate in a motor vehicle, the method comprising the steps of:
fastening an electronic assembly to the housing of the high-voltage battery, the electronic assembly comprising a printed circuit board comprising electronic components and an insulating layer arranged on an underside of the printed circuit board, wherein the insulating at least largely covers the underside of the printed circuit board; and wherein the insulating layer is configured and arranged to be a contact surface configured to enable a mounting of the electronic assembly on the housing of the high-voltage battery; and
arranging the insulation layer directly or by means of a gap filler on the housing; and
wherein the insulating layer is configured to provide high-voltage insulation.

12. A high-voltage battery, comprising:
a housing;
an electronic assembly arranged on the housing, the electronic assembly comprising a printed circuit board comprising electronic components and an insulating layer arranged on an underside of the printed circuit board, wherein the insulating at least largely covers the underside of the printed circuit board, and wherein the insulating layer is configured and arranged to be a contact surface configured to enable a mounting of the electronic assembly on the housing of the high-voltage battery; and
wherein with the insulation layer is configured to provide high-voltage insulation.
